(19) United States
(12) Patent Application Publication
(10) Pub. No.: US 2017/0062467 A1
(43) Pub. Date: Mar. 2, 2017

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventor: Hironobu HAMANAKA, Yokkaichi (JP)

(73) Assignee: Kabushiki Kaisha Toshiba, Minato-ku (JP)

(21) Appl. No.: 15/070,651

(22) Filed: Mar. 15, 2016

Related U.S. Application Data
(60) Provisional application No. 62/208,962, filed on Aug. 24, 2015.

(51) Int. Cl. H01L 27/115; H01L 21/265; H01L 21/311; H01L 21/28; H01L 29/51; H01L 29/167

(52) U.S. Cl. CPC H01L 27/11582; H01L 29/513; H01L 29/518; H01L 29/167; H01L 21/31111; H01L 21/28282; H01L 21/26513

(57) ABSTRACT

According to one embodiment, a semiconductor memory device includes a stacked body, an insulating layer, and a columnar portion. The stacked body includes a plurality of conductive layers arranged along a first direction intersecting with a major surface of the base. The columnar portion includes an insulating member, a semiconductor layer, a semiconductor film and a memory film. The insulating layer includes a first insulating part, and a second insulating part provided on the first insulating part. The first insulating part includes a first side surface intersecting with a second direction intersecting with the first direction. The second insulating part includes a second side surface intersecting with the second direction. A position in the second direction of the first side surface is different from a position in the second direction of the second side surface.

### CROSS-REFERENCE TO RELATED APPLICATIONS

This application is based upon and claims the benefit of priority from U.S. Provisional Patent Application 62/208,962, filed on Aug. 24, 2015; the entire contents of which are incorporated herein by reference.

### FIELD

Embodiments described herein relate generally to a semiconductor memory device and a method for manufacturing the same.

### BACKGROUND

In order to achieve high capacity while reducing the bit cost of a semiconductor memory device, it is effective to achieve high integration of memory cells. In recent years, there has been proposed a semiconductor memory device, which has the memory cells three-dimensionally integrated to thereby aim at achieving high integration of the memory cells. In such a semiconductor memory device, improvement in operational yield is desired.

### BRIEF DESCRIPTION OF THE DRAWINGS

FIG. 1 is a sectional view illustrating a part of a semiconductor memory device according to a first embodiment;

FIG. 2 is a sectional view illustrating the semiconductor memory device according to the first embodiment;

FIG. 3 through FIG. 11 are process sectional views illustrating the method of manufacturing the semiconductor memory device according to the embodiment;

FIG. 12 is a sectional view illustrating the semiconductor memory device according to the variation of the first embodiment;

FIG. 13 is a sectional view illustrating a semiconductor memory device according to the comparative example of the first embodiment;

FIG. 14 through FIG. 16 are process sectional views illustrating a part of a method of manufacturing the semiconductor memory device according to the comparative example of the first embodiment;

FIG. 17 is a sectional view illustrating a part of the semiconductor memory device according to a second embodiment;

FIG. 18 is a perspective view illustrating the semiconductor memory device according to the second embodiment;

FIG. 19 through FIG. 23 are process sectional views illustrating the method of manufacturing the semiconductor memory device according to the second embodiment.

### DETAILED DESCRIPTION

In general, according to one embodiment, a semiconductor memory device includes a stacked body, an insulating layer, and a columnar portion. The stacked body is provided on a base. The stacked body includes a plurality of conductive layers arranged along a first direction intersecting with a major surface of the base. The insulating layer provided on the stacked body. The columnar portion includes an insulating member, a semiconductor layer, a semiconductor film and a memory film. The insulating member extends in the first direction through the stacked body and the insulating layer. The semiconductor layer is provided on the insulating member. The semiconductor film is provided between the insulating member and the stacked body. The memory film is provided between the semiconductor film and the stacked body, and between the semiconductor film and the insulating layer. The insulating layer includes a first insulating part, and a second insulating part provided on the first insulating part. The first insulating part includes a first side surface intersecting with a second direction intersecting with the first direction. The second insulating part includes a second side surface intersecting with the second direction. A position in the second direction of the first side surface is different from a position in the second direction of Embodiment of the invention will be described hereinafter with reference to the accompanying drawings.

A first embodiment is described.

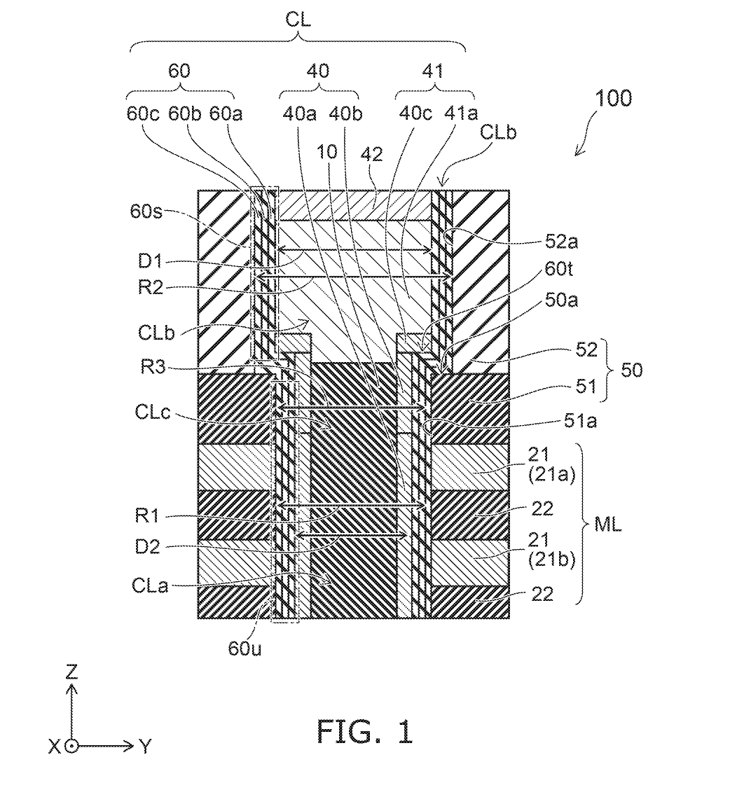

FIG. 1 is a sectional view illustrating a part of a semiconductor memory device according to the embodiment.

As illustrated in FIG. 1, a semiconductor memory device 100 according to the embodiment is provided with columnar portions CL, stacked bodies ML, and an insulating layer 50.

The columnar portions CL each include an insulating member 10, a semiconductor film 40, a semiconductor layer 41, an upper semiconductor layer 42, and a memory film 60. The insulating member 10 has, for example, a columnar shape. A direction in which the insulating member 10 extends is defined as a Z-direction. A direction perpendicular to the Z-direction (a first direction) is defined as a Y-direction (a second direction), and a direction perpendicular to the Z-direction and the Y-direction is defined as an X-direction (a third direction).

The stacked body ML includes a plurality of conductive layers 21 and a plurality of insulating layers 22. The conductive layers 21 are provided, for example, in the Z-direction so as to be spaced from each other. The conductive layers 21 are arranged in the Z-direction. Each of the insulating layers 22 is provided between the conductive layers 21. The conductive layers 21 each include a conductive material such as tungsten (W).

The conductive layers 21 include, for example, a first conductive layer 21a and a second conductive layer 21b. In the stacked body ML, the first conductive layer 21a is disposed as the uppermost layer. The second conductive layer 21b is disposed below the first conductive layer 21a via one of the insulating layers 22 as a lower layer of the first conductive layer 21a. The first conductive layer 21a included in the stacked body ML functions as, for example, a selection gate electrode. The second conductive layer 21b functions as, for example, a word line.

On the stacked body ML, there is provided the insulating layer 50. The insulating layer 50 includes a first insulating part 51 and a second insulating part 52. The second insulating part 52 is provided on the first insulating part 51.

The first insulating part 51 and the second insulating part 52 have respective compositions different in etching rate in predetermined conditions from each other. When performing the etching in the predetermined conditions, the etching rate of the second insulating part 52 is higher than the etching rate of the first insulating part 51.

The first insulating part 51 and the second insulating part 52 each include, for example, silicon oxide. The second insulating part 52 includes, for example, carbon. The carbon concentration of the second insulating part 52 is higher than the carbon concentration of the first insulating part 51. In this case, in the wet etching using dilute hydrofluoric acid (DHF), the etching rate of the second insulating part 52 is higher than the etching rate of the first insulating part 51.

The stacked body ML and the first insulating part 51 are disposed in the periphery of the insulating member 10. The insulating member 10 and the stacked body ML overlap each other in a direction parallel to the X-Y plane. The insulating member 10 and the first insulating part 51 overlap each other in the direction parallel to the X-Y plane.

Between the insulating member 10 and the stacked body ML, and between the insulating member 10 and the first insulating part 51, there is provided the semiconductor film 40. The semiconductor film 40 includes a first semiconductor region 40a and a second semiconductor region 40b.

The second semiconductor region 40b is provided on the first semiconductor region 40a. In a direction parallel to the X-Y plane, the second semiconductor region 40b does not overlap the first conductive layer 21a. Specifically, the second semiconductor region 40b is provided above the first conductive layer 21a in the Z-direction.

The semiconductor film 40 includes a semiconductor material such as silicon. The second semiconductor region 40b includes an impurity such as phosphorus (P) to be a donor. The impurity concentration of the second semiconductor region 40b is higher than the impurity concentration of the first semiconductor region 40a. For example, the first semiconductor region 40a includes an element selected from the group consisting phosphorous, arsenic and antimony. The second semiconductor region 40b includes the element selected from the group consisting phosphorous, arsenic and antimony. The element concentration of the second semiconductor region 40b is higher than the element concentration of the first semiconductor region 40a.

On the insulating member 10, there is provided the semiconductor layer 41. On the semiconductor layer 41, there is provided the upper semiconductor layer 42. The semiconductor film 40 (the second semiconductor region 40b) and the semiconductor layer 41 have contact with each other. The semiconductor layer 41 and the upper semiconductor layer 42 have contact with each other.

The semiconductor layer 41 and the upper semiconductor layer 42 include a semiconductor material such as silicon. The semiconductor layer 41 includes an impurity such as phosphorus (P) to be a donor. The upper semiconductor layer 42 includes an impurity such as arsenic (As) to be a donor.

Although the semiconductor film 40 and the semiconductor layer 41 will be described later in detail, the second insulating part 52 is disposed in the periphery of the semiconductor layer 41 and the upper semiconductor layer 42. The semiconductor layer 41 and the second insulating part 52 overlap each other in the direction parallel to the X-Y plane. The upper semiconductor layer 42 and the second insulating part 52 overlap each other in the direction parallel to the X-Y plane.

Between the semiconductor film 40 and the stacked body ML, between the semiconductor film 40 and the first insulating part 51, between the semiconductor layer 41 and the second insulating part 52, and between the upper semiconductor layer 42 and the second insulating part 52, there is provided the memory film 60. The memory film 60 includes a tunnel insulating film 60a (a first insulating film), a charge storage film 60b (an intermediate film), and a block insulating film 60c (a second insulating film).

The tunnel insulating film 60a is provided between the semiconductor film 40 and the stacked body ML, between the semiconductor film 40 and the first insulating part 51, between the semiconductor layer 41 and the second insulating part 52, and between the upper semiconductor layer 42 and the second insulating part 52.

The block insulating film 60c is provided between the tunnel insulating film 60a and the stacked body ML, and between the tunnel insulating film 60a and the insulating layer 50.

The charge storage film 60b is provided between the tunnel insulating film 60a and the block insulating film 60c.

The tunnel insulating film 60a and the block insulating film 60c each include, for example, silicon oxide. It is also possible for the tunnel insulating film 60a and the block insulating film 60c to include Al₂O₃, Y₂O₃, La₂O₃, Gd₂O₃, Ce₂O₃, CeO₂, Ta₂O₅, HfO₂, ZrO₂, TiO₂, HfSiO, HfAlO, ZrSiO, ZrAlO, or AlSiO. The charge storage film 60b includes, for example, silicon nitride (SiN).

In a direction parallel to the X-Y plane, a part of the columnar portion CL overlapping the stacked body ML is defined as a first columnar part CLa. In the direction parallel to the X-Y plane, a part of the columnar portion CL overlapping the second insulating part 52 is defined as a second columnar part CLb. In the direction parallel to the X-Y plane, a part of the columnar portion CL overlapping the first insulating part 51 is defined as a third columnar part CLc.

A diameter R1 of the first columnar part CLa is smaller than a diameter R2 of the second columnar part CLb. A diameter R3 of the third columnar part CLc is smaller than the diameter R2 of the second columnar part CLb.

Although in the embodiment, there are assumed the first columnar part CLa having a circular cylindrical shape, the second columnar part CLb having a circular cylindrical shape, and the third columnar part CLc having a circular cylindrical shape, it is also possible for the first columnar part CLa, the second columnar part CLb, and the third columnar part CLc to have, for example, an elliptic cylindrical shape. The diameter R1 of the first columnar part CLa, the diameter R2 of the second columnar part CLb, and the diameter R3 of the third columnar part CLc can be defined as, for example, effective diameters obtained from a cross-sectional area of a cross-sectional surface along a plane (the X-Y plane) perpendicular to an extending direction (the Z-direction) of the columnar portion CL.

Specifically, assuming that the cross-sectional area described above is S, and the effective diameter described above is R, the effective diameter R of the columnar portion CL (the first columnar part CLa, the second columnar part CLb, and the third columnar part CLc) corresponding to the cross-sectional area S can be obtained using the relational expression of S=π(R/2)².

The first insulating part 51 has a first side surface 51a intersecting with one direction (e.g., the Y-direction) intersecting with the Z-direction. The second insulating part 52 has a second side surface 52b intersecting with the one direction (the Y-direction). The positions of these side surfaces are different from each other in the second direction.

For example, in a direction parallel to the X-Y plane, the position of the first side surface 51a of the first insulating part 51 and the position of the second side surface 52b of the second insulating part 52 are different from each other. Specifically, the insulating layer 50 has a first step part 50a. The first step part 50a has a roughly ring-like shape. The step-like shape of the first step part 50a is transferred to the memory film 60 on the first step part 50a. The part of the memory film 60, to which the step-like shape of the first step part 50a is transferred, forms a second step part 60t. In other words, the second step part 60t is provided on the first step part 50a.

In the insulating layer 50, the first side surface 51a has contact with the second columnar part CLb, and the second side surface 52b has contact with the third columnar part CLc.

In the columnar portion CL, the memory film 60 has a cylindrical shape. The memory film 60 includes a first part 60s having a first diameter D1 between the semiconductor layer 41 and the second insulating part 52, and between the upper semiconductor layer 42 and the second insulating part 52. The memory film 60 includes a second part 60u having a second diameter D2 between the semiconductor film 40 and the stacked body ML, and between the semiconductor film 40 and the first insulating part 51. The first diameter D1 is larger than the second diameter D2. The memory film 60 has the second step part 60t between the first part 60s and the second part 60u.

The semiconductor layer 41 includes a third semiconductor region 40c and a fourth semiconductor region 41a. The third semiconductor region 40c includes an impurity such as phosphorus to be a donor. The fourth semiconductor region 41a includes an impurity such as phosphorus to be a donor. The impurity concentration of the third semiconductor region 40c is higher than the impurity concentration of the fourth semiconductor region 41a. The third semiconductor region 40c includes a part having the highest impurity concentration on the semiconductor layer 41. The third semiconductor region 40c is provided on the second step part 60t. The third semiconductor region 40c has, for example, a roughly ring-like shape. The fourth semiconductor region 41a is provided in a part of the semiconductor layer 41 other than the third semiconductor region 40c. In other words, the third semiconductor region 40c is provided in a part including an area directly above the first part 60s, but is not provided in an area directly above the insulating member 10.

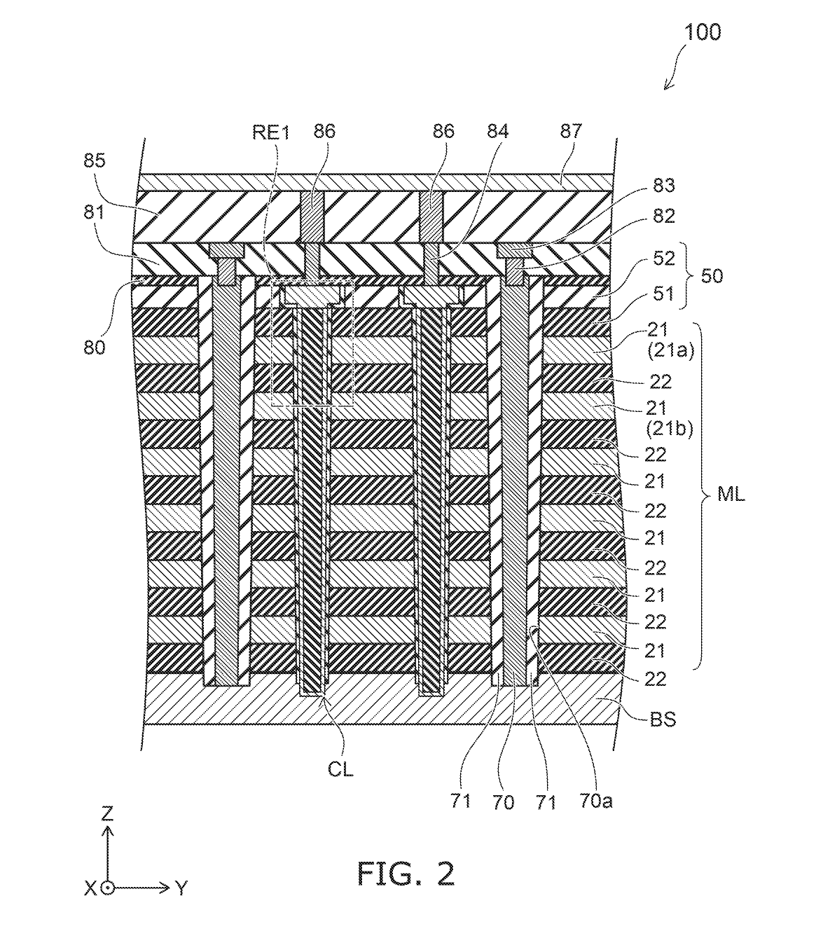

FIG. 2 is a sectional view illustrating the semiconductor memory device according to the embodiment.

An area RE1 illustrated in FIG. 2 corresponds to FIG. 1. In other words, FIG. 1 is a schematic enlarged view of the area RE1.

As shown in FIG. 2, the semiconductor memory device 100 according to the embodiment is provided with a base BS. For example, the base BS is a substrate. For example, the base BS may be a semiconductor substrate. On the base BS, there are provided the stacked body ML, the columnar portions CL, and conductive members 70. The columnar portions CL each extend along the Z-direction. The conductive members 70 each have a plate-like shape extending along the X-Z plane. In other words, the width in the Y-direction of the conductive member 70 is narrower than the width in the X-direction of the conductive member 70.

On the stacked body ML, there is provided the insulating layer 50.

The stacked body ML and the insulating layer 50 are provided in the periphery of the columnar portion CL. The stacked body ML and the columnar portions CL overlap each other in a direction parallel to the X-Y plane. The insulating layer 50 and the columnar portions CL overlap each other in the direction parallel to the X-Y plane.

On the insulating layer 50 and the columnar portions CL, there is provided an insulating layer 80.

In the periphery of the conductive member 70, there are provided the stacked body ML, the insulating layers 50, 80. The stacked body ML and the conductive member 70 overlap each other in the direction parallel to the X-Y plane. The insulating layer 50 and the conductive member 70 overlap each other in the direction parallel to the X-Y plane. The insulating layer 80 and the conductive member 70 overlap each other in the direction parallel to the X-Y plane.

Between the stacked body ML and the conductive member 70, between the insulating layer 50 and the conductive member 70, between the insulating layer 80 and the conductive member 70, there is provided an insulating film 71.

On the insulating layer 80, there is provided an insulating layer 81. Directly on the conductive member 70, there is provided a plug 82. On the plug 82, there is provided an interconnect 83 extending in the X-direction. The conductive member 70 is electrically connected to the interconnect 83 via the plug 82. Directly on the columnar portion CL, there is provided a plug 84. The plug 84 pierces the insulating layers 80, 81. On the insulating layer 81, there is provided an insulating layer 85. On the plug 84, there is provided a plug 86. On the insulating layer 85, there is provided an interconnect 87 extending in the X-direction. The interconnect 87 is electrically connected to the columnar portions CL via the respective plugs 86.

A method of manufacturing the semiconductor memory device according to the embodiment will be described.

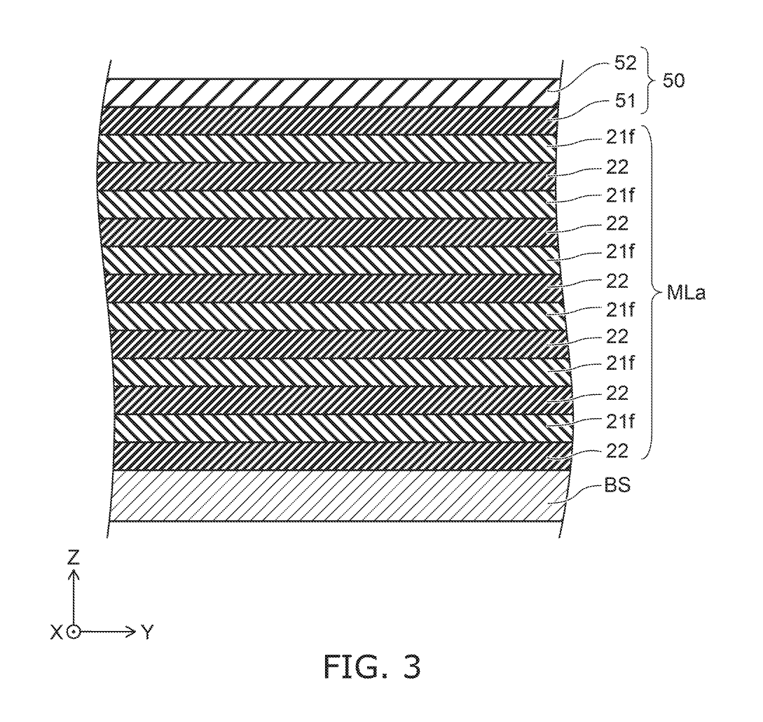

FIG. 3 through FIG. 11 are process sectional views illustrating the method of manufacturing the semiconductor memory device according to the embodiment.

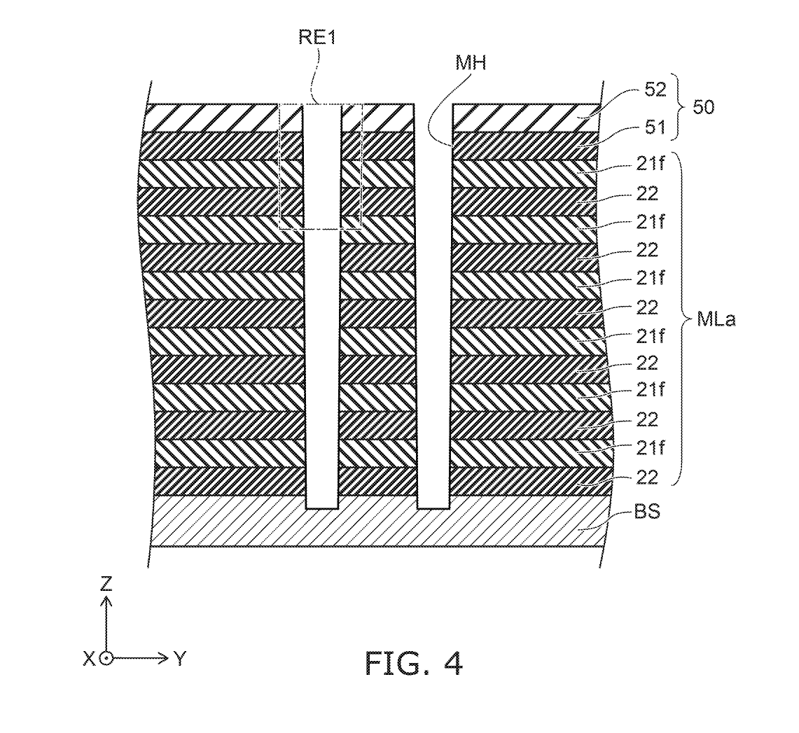

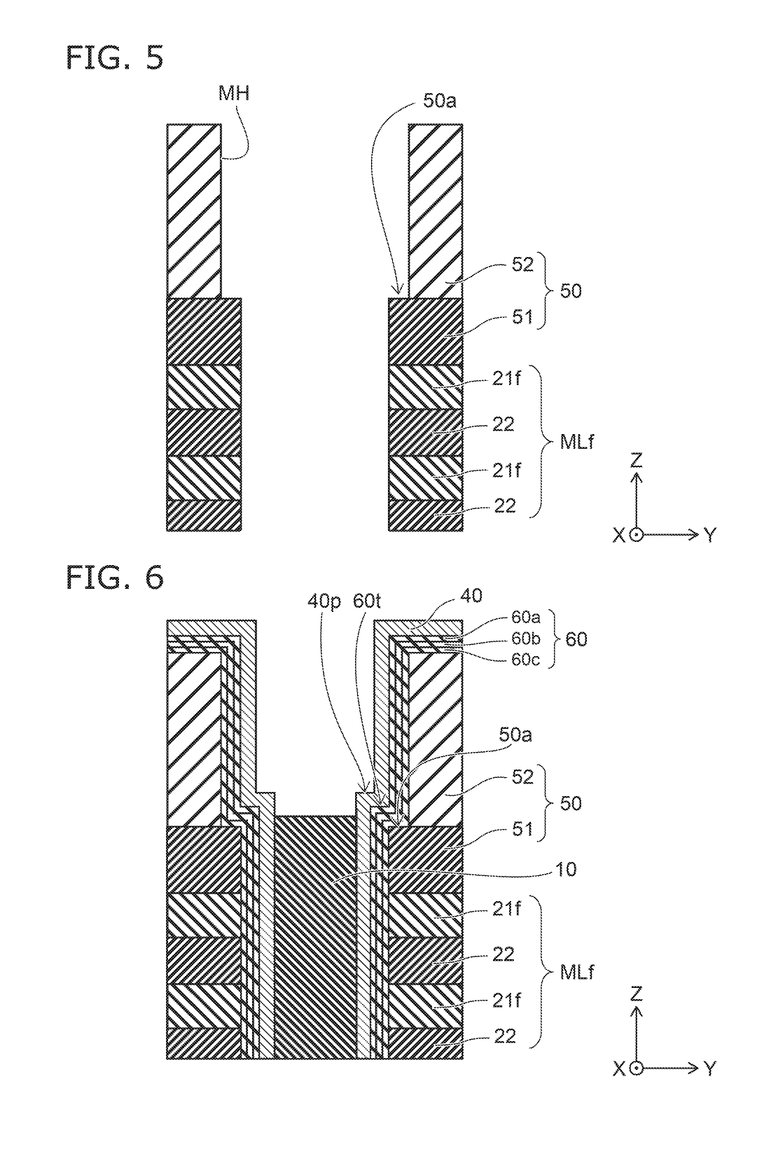

FIG. 5 through FIG. 10 each illustrate an area corresponding to the area RE1 shown in FIG. 4.

As shown in FIG. 3, a stacked body MLf including a plurality of first layers 21f and the plurality of insulating layers 22 is formed on the base BS. The first layers 21f and the insulating layers 22 are alternately stacked on the base BS. The first layers 21f are each formed using a material including, for example, silicon nitride. The insulating layers 22 are each formed using a material including, for example, silicon oxide.

The insulating layer 50 is formed on the stacked body MLf. The insulating layer 50 includes the first insulating part 51 and the second insulating part 52. The first insulating part 51 is formed on the stacked body MLf using a film deposition process such as chemical vapor deposition (CVD). The second insulating part 52 is formed on the first insulating part 51 using a film deposition process such as CVD.

The composition of the material used for forming the first insulating part 51 and the composition of the material used for forming the second insulating part 52 are different from each other. In the etching process in the predetermined conditions, the etching rate of the second insulating part 52 is higher than the etching rate of the first insulating part 51.

The first insulating part 51 is formed using a material including, for example, silicon oxide. The second insulating part 52 is formed using a material including, for example, silicon oxide and carbon. The carbon concentration of the material used for forming the second insulating part 52 is higher than the carbon concentration of the material used for forming the first insulating part 51. For example, it can be formed using a material including tetraethyl orthosilicate (TEOS, Si(OC₂H₅)₄). For example, it is also possible to form the second insulating part 52 so that the density of the second insulating part 52 is lower than the density of the first insulating part 51.

As shown in FIG. 4, memory holes MH are formed in the stacked body MLf and the insulating layer 50 using anisotropic etching such as reactive ion etching (RIE). The memory holes MH are each, for example, a hole having a circular cylindrical shape extending in the Z-direction. The memory holes MH can each have an elliptic cylindrical shape.

As shown in FIG. 5, the etching is performed in the condition that the etching rate of the second insulating part 52 is higher than the etching rate of the first insulating part 51 and the etching rate of the stacking body MLf. Due to the etching process, the first step part 50a is formed in the memory hole MH. In other words, the first step part 50a is formed by partially removing the second insulating part 52 on the first insulating part 51. The etching process is, for example, a wet-etching process using DHF.

As shown in FIG. 6, the memory film 60 is formed on the inner surface of the memory hole MH. The memory film 60 includes the tunnel insulating film 60a, the charge storage film 60b, and the block insulating film 60c. The memory film 60 is formed by stacking the block insulating film 60c, the charge storage film 60b, and the tunnel insulating film 60a on the inner surface of the memory hole MH in this order.

The tunnel insulating film 60a and the block insulating film 60c are each formed using, for example, silicon oxide. It is also possible for the tunnel insulating film 60a and the block insulating film 60c to be formed using Al₂O₃, Y₂O₃, La₂O₃, Gd₂O₃, Ce₂O₃, CeO₂, Ta₂O₅, HfO₂, ZrO₂, TiO₂, HfSiO, HfAlO, ZrSiO, ZrAlO, or AlSiO. The charge storage film 60b can be formed using, for example, silicon nitride (SiN).

The shape of the first step part 50a is transferred to the memory film 60. Specifically, the part formed on the first step part 50a in the memory film 60 becomes the second step part 60t. The semiconductor film 40 is formed on the memory film 60.

Subsequently, the memory film 60 and the semiconductor film 40 formed on the bottom of the memory hole MH are partially removed by anisotropic etching such as RIE. Thus, the base BS is exposed on the bottom of the memory hole MH. After partially removing the memory film 60 and the semiconductor film 40 on the bottom of the memory hole MH, the semiconductor film is further formed in the memory hole MH. The semiconductor film forms a part of the semiconductor film 40. Thus, the semiconductor film 40 is electrically connected to the surface of the base SB. In the semiconductor film 40, in a part on the second step part 60t, there is formed a third step part 40p.

The memory hole MH is filled with an insulating material. Subsequently, an etch back process is performed to the extent that the third step part 40p is exposed. Thus, the insulating member 10 is formed in the memory hole MH. The insulating member 10 fills the memory hole MH below the second step part 60t.

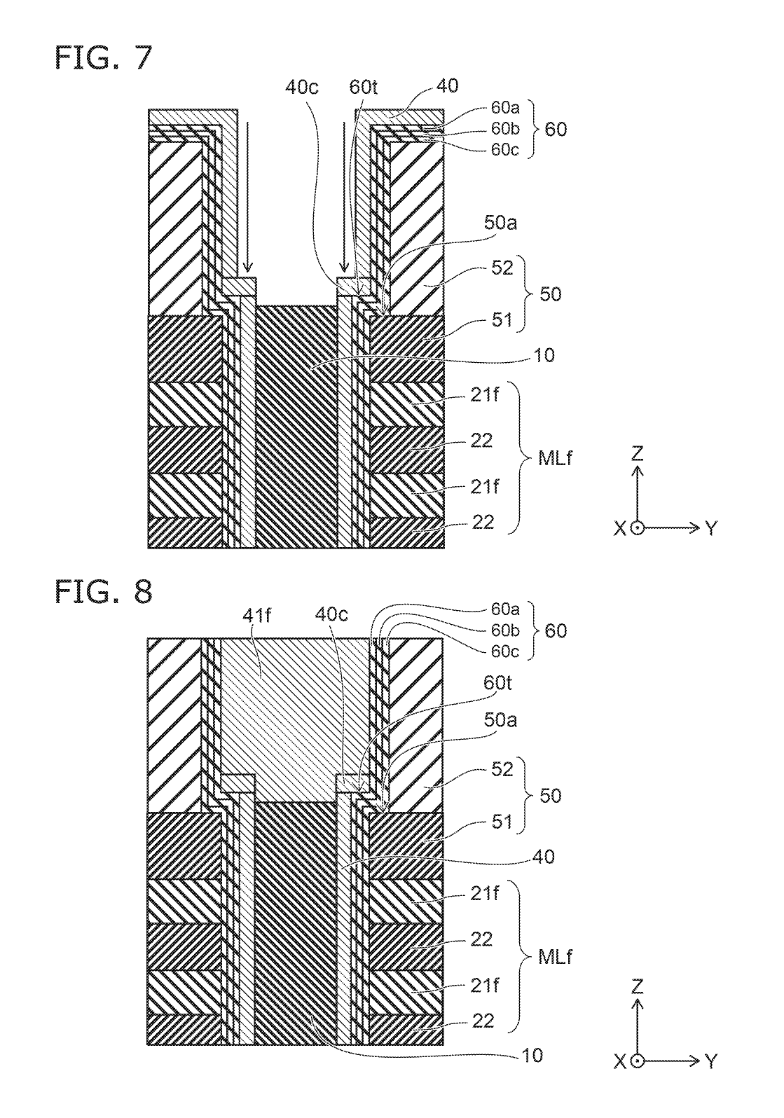

As shown in FIG. 7, an impurity such as phosphorus to be a donor is injected in the surface of the third step part 40p using ion injection. Thus, a part of the semiconductor film 40 including the third step part 40p forms the third semiconductor region 40c. The third semiconductor region 40c has a roughly ring-like shape. The third semiconductor region 40c is a diffusion source of the impurity.

As shown in FIG. 8, a semiconductor layer 41f is formed on the insulating member 10. Thus, the semiconductor layer 41f fills the memory hole MH. Subsequently, etch back is performed to expose the upper surface of the second insulating part 52.

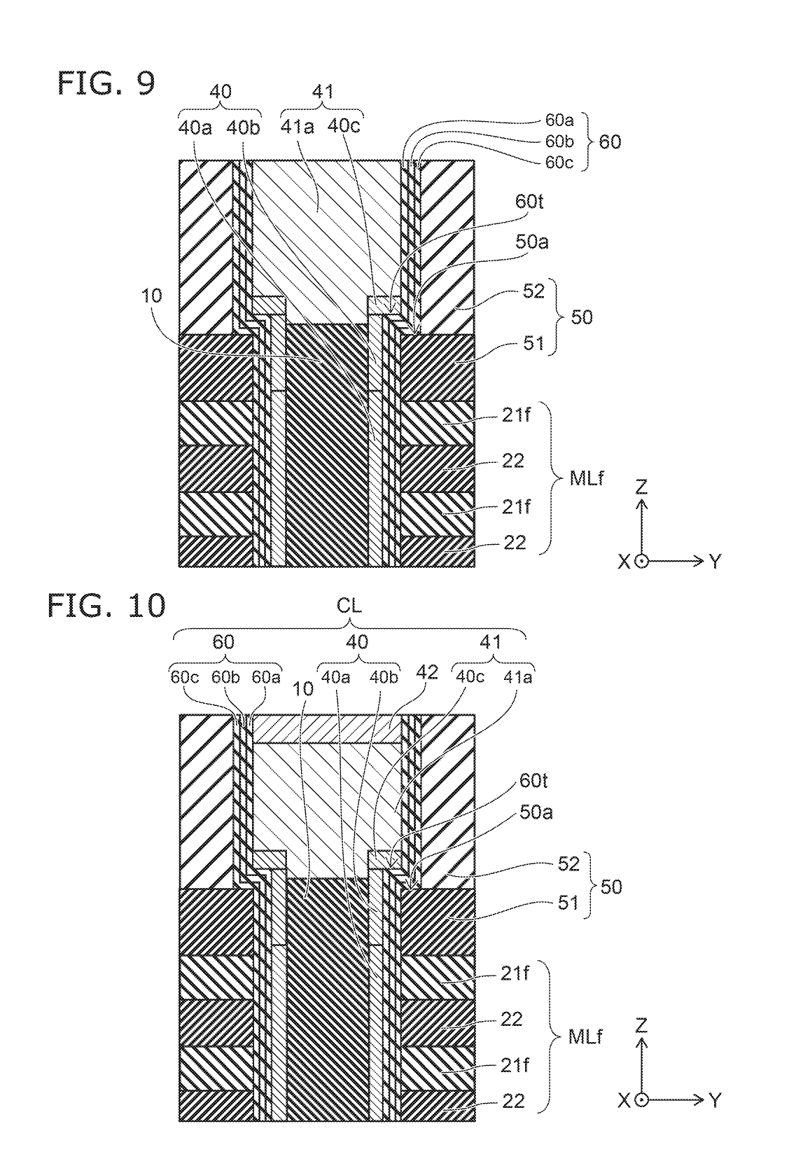

As shown in FIG. 9, an impurity such as phosphorus is injected in the semiconductor layer 41f using ion injection. Thus, the semiconductor layer 41f turns to the fourth semiconductor region 41a. Further, the impurity is diffused from the third semiconductor region 41a as the diffusion source of the impurity to the semiconductor film 40. Thus, a part of the semiconductor film 40 turns to the second semiconductor region 40b. A part of the semiconductor film 40 other than the second semiconductor region 40b turns to the first semiconductor region 40a lower in impurity concentration than the second semiconductor region 40b. For example, a part of the semiconductor film 40 located higher than the first layer 21f in the Z-direction turns to the second semiconductor region 40b.

As shown in FIG. 10, an impurity such as arsenic to be a donor is injected in the surface of the fourth semiconductor region 41a using ion injection. Thus, an upper part of the fourth semiconductor region 41a turns to the upper semiconductor layer 42. The third semiconductor region 40c and the fourth semiconductor region 41a turn to the semiconductor layer 41. Thus, the columnar portions CL are formed.

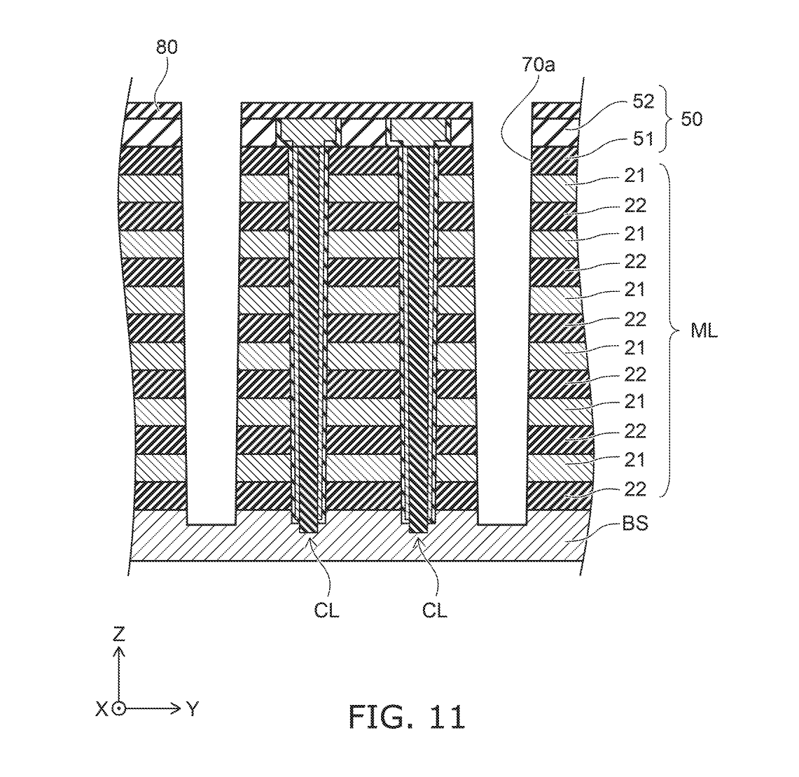

As shown in FIG. 11, the insulating layer 80 is formed on the insulating layer 50 and the columnar portions CL. Slits 70a are formed in the insulating layer 80 and the stacked body ML. By performing etching through the slits 70a, the first layers 21f are removed. Thus, the part from which the first layers 21f are removed forms a cavity section. A conductive material is deposited in the cavity section via the slits 70a. Thus, the conductive layers 21 are formed in the cavity section. Thus, the stacked body MLf turns to the stacked body ML.

As shown in FIG. 2, the insulating film 71 is formed on the exposed surface of the stacked body ML in the slits 70a. Subsequently, the conductive material is provided in the slits 70a. Thus, the conductive member 70 is formed in each of the slits 70a. The insulating layer 81 is formed on the insulating layer 80. In an area directly on the conductive member 70, there is formed the plug 82. In an area directly on each of the plugs 82, there is formed the interconnect 83. In an area directly on each of the columnar portions CL, there is formed the plug 84. The insulating layer 85 is formed on the insulating layer 81. In an area directly on each of the plugs 84, there is formed the plug 86. The interconnect 87 is formed on the insulating layer 85. The interconnect 87 and the columnar portions CL are electrically connected to each other via the respective plugs 86, 84.

The semiconductor memory device 100 according to the embodiment is manufactured through the processes described hereinabove.

In the embodiment, the third semiconductor region 40c locally exists between the semiconductor film 40 (the second semiconductor region 40b) and the fourth semiconductor region 41a. Thus, the electric resistance between the semiconductor film (the second semiconductor region 40b) and the fourth semiconductor region 41a is locally reduced.

A semiconductor memory device according to a variation of the first embodiment will be described.

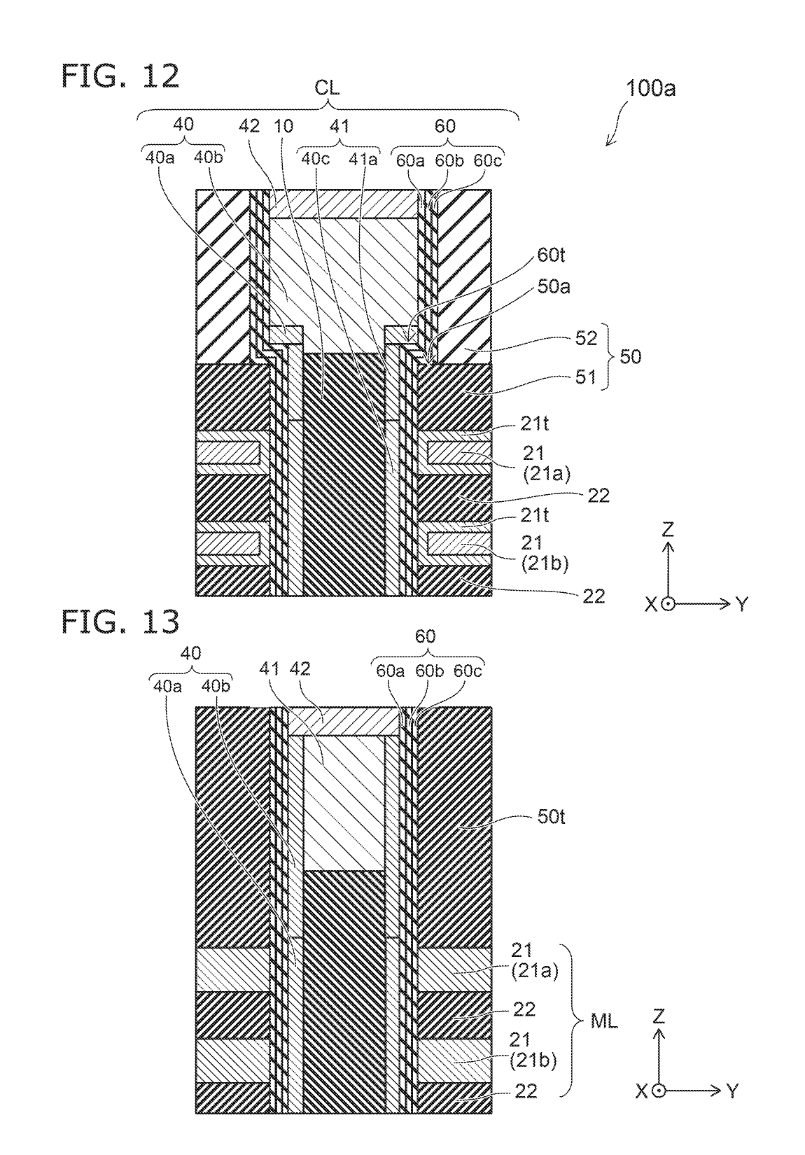

FIG. 12 is a sectional view illustrating the semiconductor memory device according to the variation of the first embodiment.

FIG. 12 corresponds to the area RE1 shown in FIG. 2.

As shown in FIG. 12, in a semiconductor memory device 100a according to the variation, conductive films 21t are provided between the conductive layers 21 and the memory film 60, and between the conductive layers 21 and the insulating layers 22, respectively. The conductive layers 21t each include, for example, titanium nitride.

Other configurations and advantages are substantially the same as those of the first embodiment.

A comparative example of the first embodiment will be described.

FIG. 13 is a sectional view illustrating a semiconductor memory device according to the comparative example of the first embodiment.

FIG. 13 corresponds to the area RE1 shown in FIG. 2.

As shown in FIG. 13, in the comparative example, an insulating layer 50t is provided instead of the insulating layer 50. The insulating layer 50t is a single insulating layer homogenous in composition.

In the comparative example, unlike the first embodiment, the first step part 50a and the second step part 60t are not provided. On the insulating member 10, there is provided a semiconductor layer 41c including an impurity.

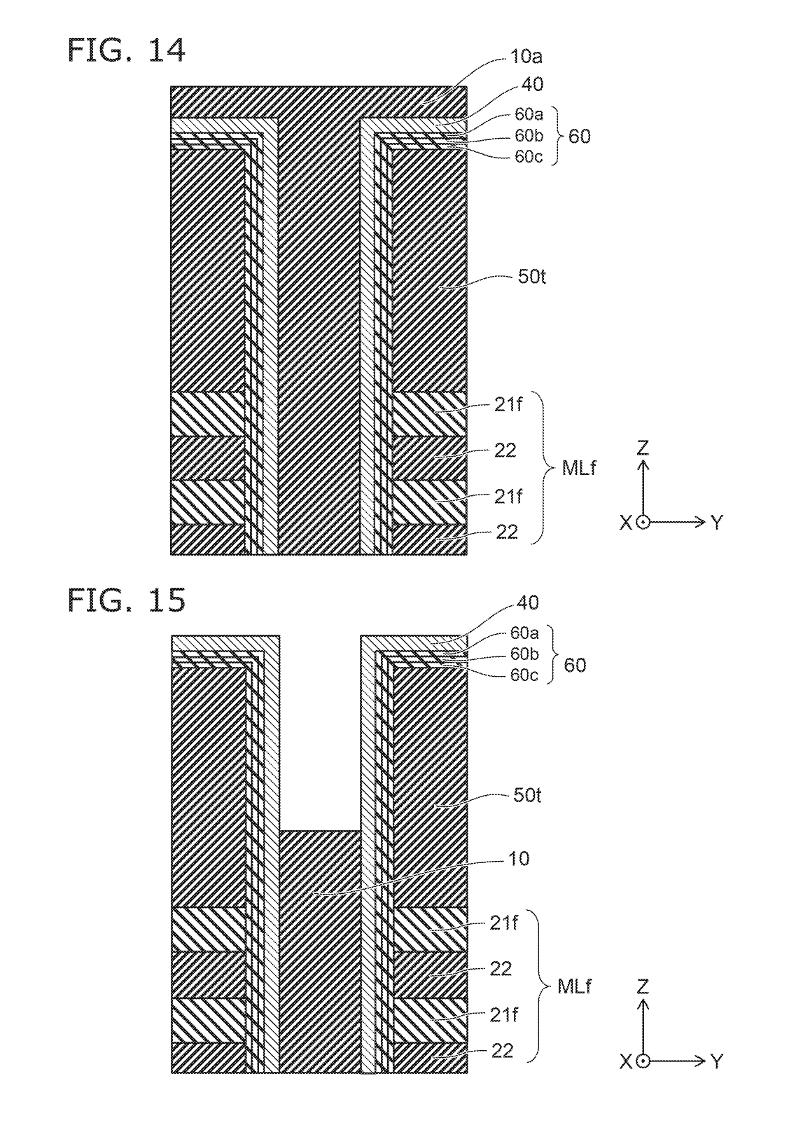

FIG. 14 through FIG. 16 are process sectional views illustrating a part of a method of manufacturing the semiconductor memory device according to the comparative example of the first embodiment.

In the comparative example, as shown in FIG. 14, the memory hole MH is filled by depositing an insulating material 10a. Subsequently, etch back is performed as shown in FIG. 15. Thus, the insulating member 10 is formed in the memory hole MH. On this occasion, in the Z-direction, there is caused a variation in the height of the upper surface of the insulating member 10.

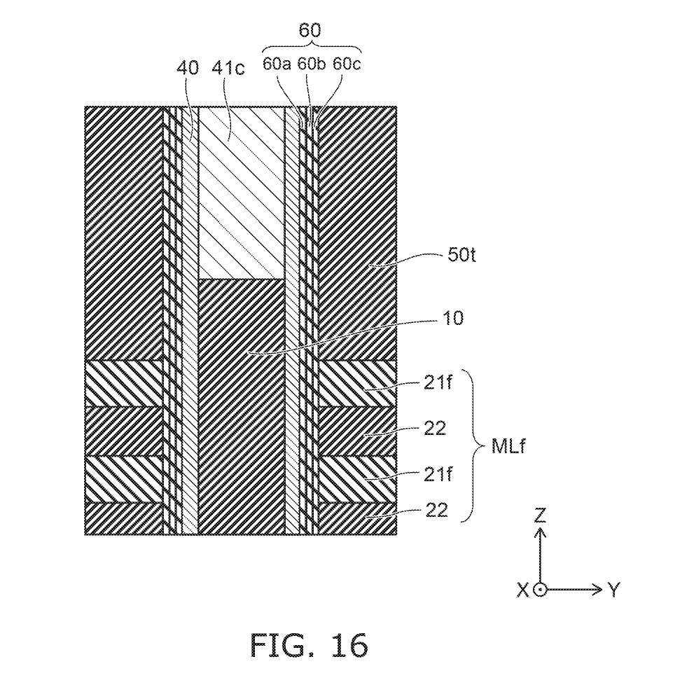

As shown in FIG. 16, the semiconductor layer 41c including an impurity such as phosphorous to be a donor is formed on the insulating member 10. The semiconductor layer 41c is an impurity diffusion source.

As shown in FIG. 13, the impurity is diffused from the semiconductor layer 41c to a part of the semiconductor film 40, and thus, the part of the semiconductor film 40 turns to the second semiconductor region 40b including the impurity. The rest of the semiconductor film 40 turns to the first semiconductor region 40a lower in impurity concentration than the second semiconductor region 40b.

The variation in height in the Z-direction of the semiconductor layer 41c as the impurity diffusion source depends on the variation in height of the upper surface of the insulating member 10. Specifically, the variation in etching when forming the insulating member 10 becomes the variation in height of the semiconductor layer 41c.

Since there is a variation in height of the diffusion source of the impurity, there is a variation in height of the second semiconductor region 40b. For example, if there is a variation in the distance between the second semiconductor region 40b and the conductive layer 21 (e.g., the conductive layer 21a) in the Z-direction, the operational yield of the conductive layer 21a as the selection gate electrode is damaged.

In contrast, in the first embodiment, the first insulating part 51 and the second insulating part 52 are provided on the stacked body ML. Due to the first insulating part 51 and the second insulating part 52, the first step part 50a is formed. In other words, the insulating layer 50 provided on the stacked body ML includes the first step part 50a inside.

On the first step part 50a, there is formed the second step part 60t of the memory film 60. On the second step part 60t, there is formed the diffusion source (the third semiconductor region 40c) of the impurity. The diffusion source locally exists on the second step part 60t. The height variation in the Z-direction of the diffusion source depends mainly on the variation in film thickness of the first insulating part 51. In other words, the variation in distance between the second step part 60t and the first conductive layer 21a depends mainly on the variation in deposition of the first insulating part 51.

The first insulating part 51 is formed using, for example, a CVD process. Therefore, the variation in film thickness of the first insulating part 51 is smaller than the height variation of the upper surface of the insulating member 10 formed using an etching process.

Therefore, in the first embodiment, unlike the comparative example of the first embodiment, the variation in position in the Z-direction of the diffusion source does not depend on the variation due to the etching process relatively large in variation, but depends on the deposition variation in the deposition process such as CVD. Therefore, the controllability in the Z-direction of the diffusion source is improved.

Thus, it is possible to, for example, inhibit the second semiconductor region 40b from overlapping the conductive layer 21a (e.g., the selection gate electrode) in a direction parallel to the X-Y plane. In other words, the variation in the height direction (the Z-direction) of the second semiconductor region 40b is suppressed. Therefore, the operational yield of the conductive layer 21a (the selection gate) is improved.

A semiconductor memory device according to a second embodiment will be described.

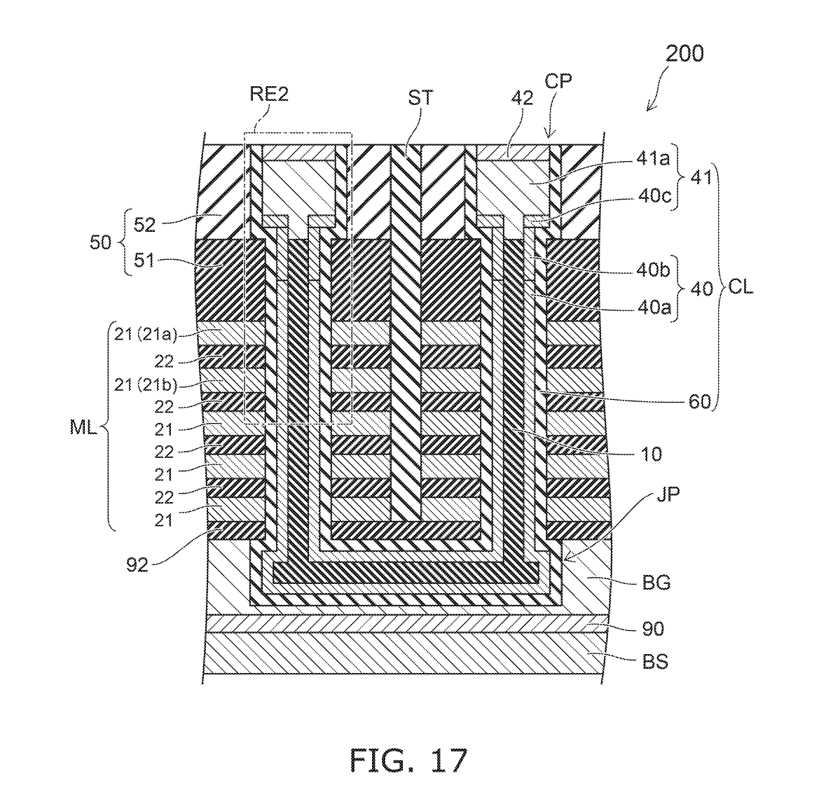

FIG. 17 is a sectional view illustrating a part of the semiconductor memory device according to the second embodiment. FIG. 17 is a sectional view illustrating a pair of columnar portions CL and the periphery thereof.

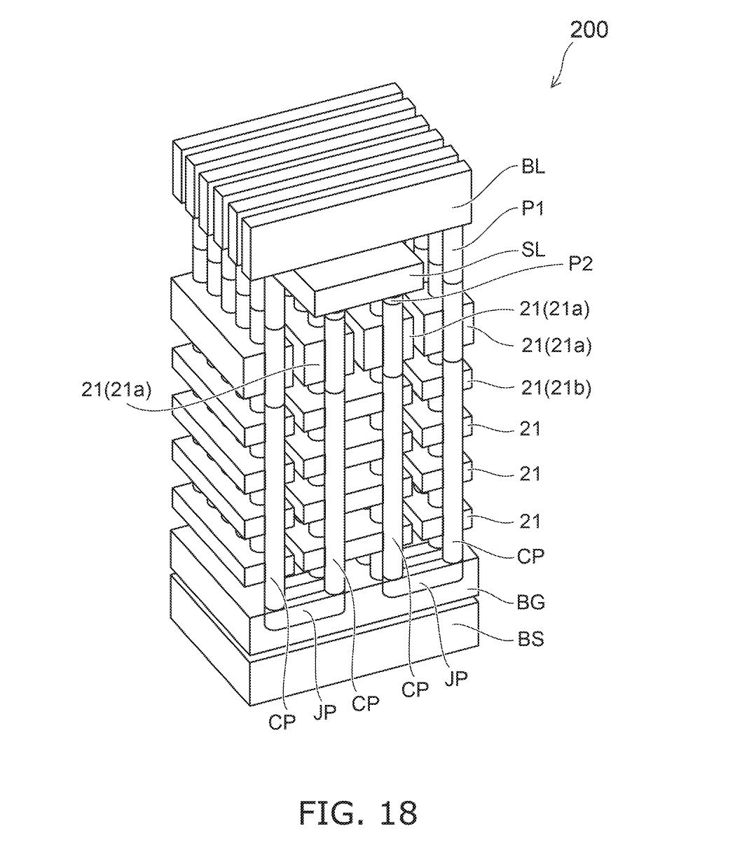

FIG. 18 is a perspective view illustrating the semiconductor memory device according to the second embodiment.

As shown in FIG. 17, a semiconductor memory device 200 according to the embodiment is provided with the base BS. On the base BS, there is provided a back gate electrode film BG via an interlayer insulating film 90. In the inside of the back gate electrode film BG, there are provided connecting portions JP. On the back gate electrode film BG, there are provided an interlayer insulating film 92, the stacked body ML, the insulating layer 50, the columnar portions CL, and an insulating member ST.

The stacked body ML is provided on the interlayer insulating film 92. The stacked body ML includes the plurality of conductive layers 21 and the plurality of insulating layers 22. The conductive layers 21 are stacked in the Z-direction so as to be spaced from each other. Each of the insulating layers 22 is provided between the conductive layers 21. The conductive layers 21 include, for example, the first conductive layer 21a and the second conductive layer 21b.

The insulating layer 50 includes the first insulating part 51 and the second insulating part 52. The second insulating part 52 is provided on the first insulating part 51.

The insulating member ST has a plate-like shape extending along the X-Z plane. In other words, the width in the Y-direction of the insulating member ST is narrower than the width in the X-direction of the insulating member ST.

The columnar portions CL are electrically connected to the connecting portion JP. The two columnar portions CL are electrically connected to each other via the connecting portion JP. In other words, the connecting portion JP connects lower ends of the pair of columnar portions CL to each other. Thus, the two columnar portions CL and the connecting portion JP constitute a U-shaped structure. In the Y-direction, the insulating member ST is disposed between the pair of columnar portions CL. The stacked body ML is provided in the periphery of the columnar portions CL and the insulating member ST. The insulating layer 50 is provided in the periphery of the columnar portions CL and the insulating member ST.

The columnar portions CL and the interlayer insulating film 92 overlap each other in the direction parallel to the X-Y plane. The columnar portions CL and the stacked body ML overlap each other in the direction parallel to the X-Y plane. The columnar portions CL and the insulating layer 50 overlap each other in an X-Y direction. The insulating member ST and the stacked body ML overlap each other in the X-Y direction. The insulating member ST and the insulating layer 50 overlap each other in the X-Y direction.

The configuration of the columnar portions CL in the insulating layer 50 is substantially the same as in the first embodiment. Specifically, the area RE2 shown in FIG. 17 corresponds to FIG. 1.

As shown in FIG. 18, an upper end of one columnar portion CL out of the pair of columnar portions CL is electrically connected to a bit line BL via a plug P1. An upper end of the other columnar portion CL is electrically connected to a source line SL via a plug P2.

Then, a method of manufacturing the semiconductor memory device according to the embodiment will be described.

FIG. 19 through FIG. 23 are process sectional views illustrating the method of manufacturing the semiconductor memory device according to the embodiment.

As shown in FIG. 19, the interlayer insulating film 90 is formed on the base BS. On the interlayer insulating film 90, there is formed the back gate electrode film BG. The back gate electrode film BG is provided with a groove GBa. The groove GBa is formed by, for example, etching the back gate electrode film BG. The groove GBa thus formed is filled with a sacrifice film 91a. On this occasion, an upper surface of a protruded part of the back gate electrode film BG and an upper surface of the sacrifice film 91a constitute a coplanar flat surface. The stacked body ML is formed on the flat surface.

The first insulating part 51 is formed on the stacked body ML. The second insulating part 52 is formed on the first insulating part 51. Thus, the insulating layer 50 including the first insulating part 51 and the second insulating part 52 is formed on the stacked body ML.

The plurality of memory holes MH is formed using anisotropic etching such as RIE. The memory holes MH each reach the sacrifice film 91a. Thus, the sacrifice film 91 is exposed on the bottom of the memory hole MH.

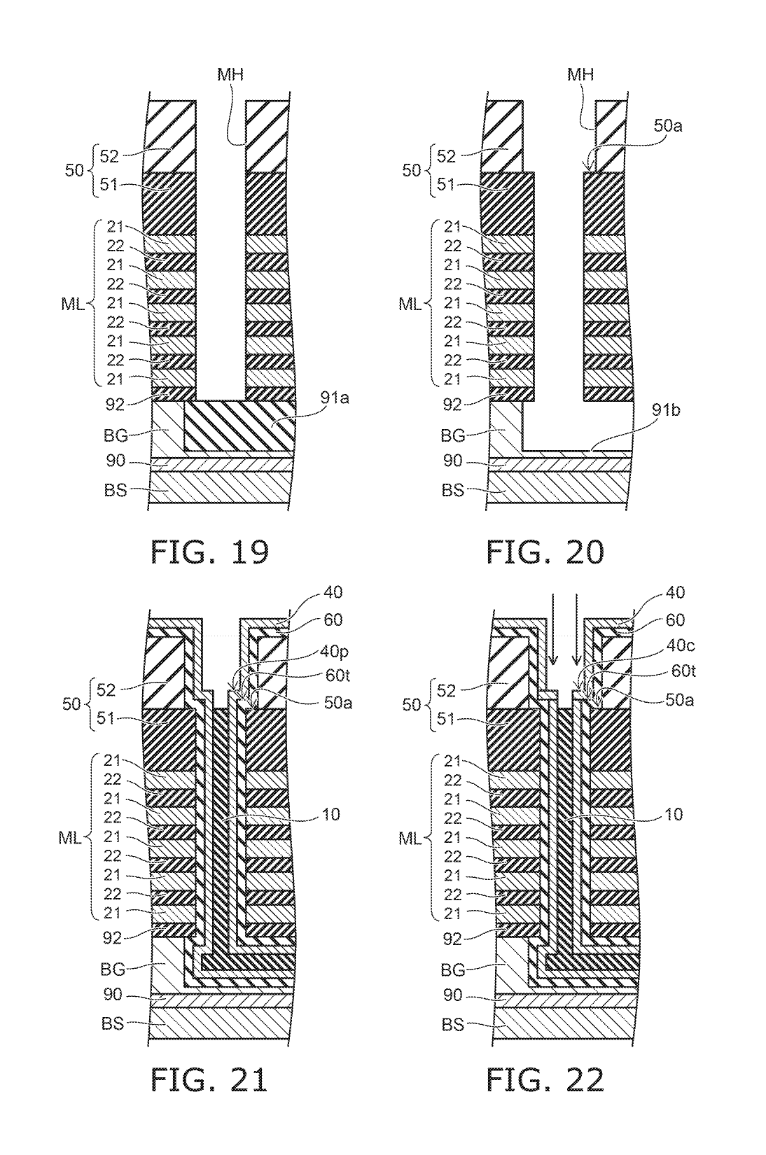

As shown in FIG. 20, the etching is performed in the condition that the etching rate of the second insulating part 52 is higher than the etching rate of the first insulating part 51 and the etching rate of the stacking body MLf. Due to the etching process, the first step part 50a is formed in the memory hole MH. In other words, the first step part 50a is formed by partially removing the second insulating part 52 on the first insulating part 51. The etching process is, for example, a wet-etching process using hydrofluoric acid. It is also possible to remove the sacrifice film 91a at the same time in this etching process. The sacrifice film 91a can also be removed in an etching process in other conditions.

By removing the sacrifice film 91a, a gap section 91b is formed between the back gate electrode film BG and the stacked body ML. The two memory holes MH are communicated with each other by the gap section 91b. Although not shown in the drawings, a U-shaped hole is formed with the gap section 91b and the pair of memory holes MH communicated with each other by the gap section 91b.

As shown in FIG. 21, the memory film 60 is formed on the inner surface of the memory holes MH and on the inner surface of the gap section 91b. The memory film 60 includes the tunnel insulating film 60a, the charge storage film 60b, and the block insulating film 60c. The memory film 60 is formed by stacking the block insulating film 60c, the charge storage film 60b, and the tunnel insulating film 60a in this order on the inner surface of the memory holes MH and the inner surface of the gap section 91b. The shape of the first step part 50a is transferred to the memory film 60. Specifically, on the first step part 50a, there is formed the second step part 60t in the memory film 60. The semiconductor film 40 is formed on the memory film 60. The shape of the second step part 60t is transferred to the semiconductor film 40. Specifically, on the second step part 60t, the third step part 40p is formed in the semiconductor film 40.

Subsequently, the insulating material is deposited. Thus, the memory holes MH and the gap section 91b are filled with the insulating material such as silicon oxide. By performing the etch back process, the insulating material thus deposited is removed to the extent that the third step part 40p is exposed. Thus, the insulating member 10 is formed in the memory holes MH and the gap section 91b. The insulating member 10 fills them below the insulating layer 50 in the Z-direction.

As shown in FIG. 22, an impurity such as phosphorus is injected in a part including the third step part 40p of the semiconductor film 40 using ion injection. Thus, the third semiconductor region 40c is formed. The third semiconductor region 40c has a roughly ring-like shape.

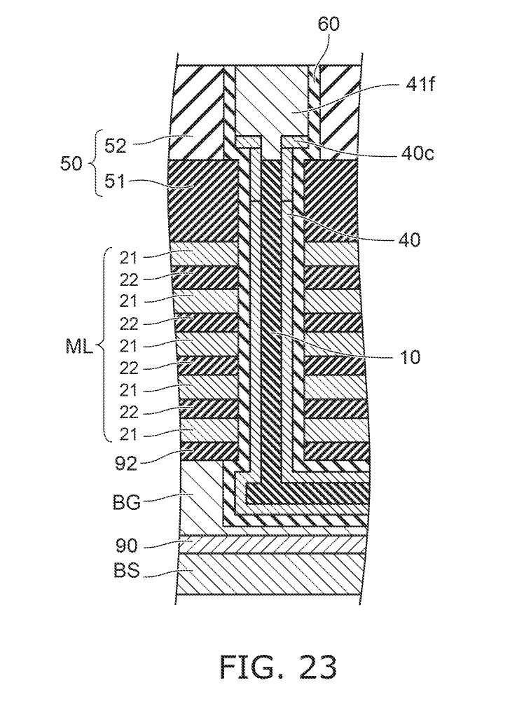

As shown in FIG. 23, the semiconductor material such as silicon is deposited. Subsequently, an etch back process is performed to thereby expose the upper surface of the insulating layer 50. Thus, the semiconductor layer 41f is formed on the insulating member 10. Thus, the semiconductor layer 41f fills the memory holes MH.

As shown in FIG. 17, an impurity such as phosphorus to be a donor is injected in the semiconductor layer 41f using ion injection. Thus, the semiconductor layer 41f turns to the fourth semiconductor region 41a. An impurity such as arsenic to be a donor is injected in the surface of the fourth semiconductor region 41a using ion injection. Thus, an upper part of the fourth semiconductor region 41a turns to the upper semiconductor layer 42. The third semiconductor region 40c and the fourth semiconductor region 41a turn to the semiconductor layer 41.

The semiconductor memory device 200 according to the embodiment is manufactured through the manufacturing processes described above.

Similarly to the first embodiment, in the embodiment, the diffusion source is provided on the first step part 50a provided in the insulating layer 50. Therefore, the variation in position in the Z-direction of the diffusion source does not depend on the variation in etching in the insulating member 10, but depends on the variation in deposition of the first insulating part 51. The variation in deposition of the first insulating part 51 is smaller than the variation due to the etching process in the insulating member 10. Therefore, the controllability in the Z-direction of the diffusion source is improved.

Thus, the operational yield of the selection gate can be improved. Further, the third semiconductor region 40c locally exists between the semiconductor film 40 (the second semiconductor region 40b) and the fourth semiconductor region 41a. Thus, the electric resistance between the semiconductor film (the second semiconductor region 40b) and the fourth semiconductor region 41a is locally reduced.

According to the embodiments described hereinabove, it is possible to realize the semiconductor memory device and the method of manufacturing the semiconductor memory device each having the operational yield improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor memory device comprising:
a stacked body provided on a base, and including a plurality of conductive layers arranged along a first direction intersecting with a major surface of the base;
an insulating layer provided on the stacked body; and
a columnar portion provided in the stacked body and the insulating layer, the columnar portion including
an insulating member extending in the first direction through the stacked body and the insulating layer,
a semiconductor layer provided on the insulating member in the insulating layer,
a semiconductor film provided between the insulating member and the stacked body, and
a memory film provided between the semiconductor film and the stacked body, and between the semiconductor film and the insulating layer,
the insulating layer including a first insulating part, and a second insulating part provided on the first insulating part,
the first insulating part including a first side surface intersecting with a second direction intersecting with the first direction, the first side surface opposing the columnar portion,
the second insulating part including a second side surface intersecting with the second direction, the second insulating part opposing the columnar portion, and
a position in the second direction of the first side surface being different from a position in the second direction of the second side surface.

2. The device according to claim 1, wherein
a composition of the first insulating part is different from a composition of the second insulating part.

3. The device according to claim 2, wherein
an etching rate of the second insulating part with respect to dilute hydrofluoric acid is higher than an etching rate of the first insulating part with respect to the dilute hydrofluoric acid.

4. The device according to claim 2, wherein
a carbon concentration in the second insulating part is higher than a carbon concentration in the first insulating part.

5. The device according to claim 1, wherein
the memory film includes
a first part provided in the second insulating part, the first part having a cylindrical shape extending in the first direction and having a first diameter, and
a second part provided in the stacked body and the first insulating part, the second part having a cylindrical shape extending in the first direction and having a second diameter,
a position of the second part in the first direction is located between a position of the first part in the first direction and a position of the base in the first direction, and
the first diameter is larger than the second diameter.

6. The device according to claim 1, wherein
the semiconductor film includes
a first semiconductor region provided between the stacked body and the insulating member, and
a second semiconductor region provided between the first insulating part and the insulating member,
a concentration of a element in the first semiconductor region is lower than a concentration of the element in the second semiconductor region, the element selected from the group consisting of phosphorous, arsenic and antimony, and
the first semiconductor region and the plurality of conductive layers fail to overlap each other in the second direction.

7. The device according to claim 1, wherein
the memory film includes
an intermediate film provided between the semiconductor film and the stacked body, and between the semiconductor layer and the insulating layer,
a first insulating film provided between the semiconductor film and the intermediate film, and between the semiconductor layer and the intermediate film, and
a second insulating film provided between the intermediate film and the stacked body, and between the intermediate film and the insulating layer.

8. The device according to claim 1, wherein
the semiconductor layer includes
a third semiconductor region provided on the second part, and
a fourth semiconductor region provided on the insulating member and the third semiconductor region,
an impurity concentration in the third semiconductor region is higher than an impurity concentration in the fourth semiconductor region, and
the third semiconductor region fails to overlap the insulating member in the first direction.

9. The device according to claim 8, wherein
the third semiconductor region has a ring-like shape surrounding at least a part of the fourth semiconductor region.

10. The device according to claim 8, wherein
the semiconductor film includes
a first semiconductor region provided between the stacked body and the insulating member, and
a second semiconductor region provided between the first insulating part and the insulating member,
a concentration of an element in the first semiconductor region is lower than a concentration of the element in the second semiconductor region, the element selected from the group consisting of phosphorous, arsenic and antimony,
the second semiconductor region has contact with the third semiconductor region, and
the first semiconductor region fails to overlap the plurality of conductive layers in the second direction.

11. A semiconductor memory device comprising:
a columnar portion extending in a first direction, and including a first columnar part, a second columnar part arranged side by side with the first columnar part in the first direction, and a third columnar part located between the first columnar part and the second columnar part;
a stacked body provided in a periphery of the first columnar part, intersecting with the first columnar part in a second direction intersecting with the first direction, and including a plurality of conductive layers arranged in the first direction;
a first insulating part provided in a periphery of the third columnar part, and intersecting with the third columnar part in the second direction; and
a second insulating part provided in a periphery of the second columnar part, and intersecting with the second columnar part in the second direction,
a diameter of the second columnar part being larger than a diameter of the third columnar part.

12. The device according to claim 11, wherein
the diameter of the second columnar part is larger than a diameter of the first columnar part.

13. The device according to claim 11, wherein
the first insulating part and the second insulating part are different in composition from each other.

14. The device according to claim 11, wherein
an etching rate of the second insulating part with respect to dilute hydrofluoric acid is higher than an etching rate of the first insulating part with respect to the dilute hydrofluoric acid.

15. The device according to claim 11, wherein
a carbon concentration in the second insulating part is higher than a carbon concentration in the first insulating part.

16. A method of manufacturing a semiconductor memory device, comprising:
stacking a plurality of first layer in a first direction so as to be spaced from each other to form a stacked body;
forming a first insulating part on the stacked body;
forming a second insulating part on the first insulating part;
forming a hole piercing the second insulating part, the first insulating part, and the stacked body;
etching the second insulating part in a condition, in which an etching rate of the second insulating part is higher than an etching rate of the first insulating part, to form a step part; and
forming a columnar portion in the hole.

17. The method according to claim 16, wherein
the forming of a columnar portion includes
forming a memory film in the hole,
forming a semiconductor film in the hole,
forming an insulating member in the hole,
injecting an impurity in a part on the step part of the semiconductor film,
forming a semiconductor layer on the insulating member, and
injecting an impurity in the semiconductor layer.
